(19) United States
(12) Patent Application Publication
(10) Pub. No.: US 2014/0335271 A1
(43) Pub. Date: Nov. 13, 2014

(54) BOATS CONFIGURED TO OPTIMIZE VAPORIZATION OF PRECURSOR MATERIALS BY MATERIAL DEPOSITION APPARATUSES

(71) Applicant: HzO, Inc., Draper, UT (US)

(72) Inventors: James Dempster, Reno, NV (US); Jason Maynard, Salt Lake City, UT (US)

(21) Appl. No.: 14/445,628

(22) Filed: Jul. 29, 2014

Related U.S. Application Data
(63) Continuation-in-part of application No. 29/491,643, filed on May 22, 2014.
Application No. 29/491,643 is a continuation-in-part of application No. 29/484,069, filed on Mar. 5, 2014.
Application No. 29/484,069 is a continuation-in-part of application No. 29/482,760, filed on Feb. 21, 2014.
Application No. 29/482,760 is a continuation-in-part of application No. 13/737,737, filed on Jan. 9, 2013.
(60) Provisional application No. 61/585,150, filed on Jan. 10, 2012.
(60) Provisional application No. 61/946,709, filed on Mar. 1, 2014.

(51) Int. Cl. F27D 3/12; C23C 14/24

(52) U.S. Cl. CPC F27D 3/12; C23C 14/243
USPC 427/248.1; 118/726; 118/727; 432/253

(57) ABSTRACT

A boat according to this disclosure includes side walls and a base that are arranged to define a container with an interior. A bottom of the boat may have a convex configuration. In a specific embodiment, the base may have a convex configuration, such as the shape of a portion of the curved surface of a cylinder, with end walls located at opposite ends of the base. Such a boat may have a crescent configuration. Each boat may be configured to be positioned against another boat, enabling the assembly of groups of boats. Multi-celled structures that receive and effectively increase the surface area of precursor material are also disclosed. A multi-celled structure may be configured for use within the interior of a boat, or individually, without a separate boat. Vaporization chambers that are configured to receive the boats and/or multi-celled structures and material deposition apparatuses that include the vaporization chambers are also disclosed, as are methods for introducing precursor materials into material deposition apparatuses.

### CROSS-REFERENCE TO RELATED APPLICATIONS

This application is a continuation-in-part of: (i) U.S. Design Patent Application No. 29/491,643, filed on May 22, 2014 and titled “BOAT FOR A DEPOSITION APPARATUS,” (“the '643 Design Application”); (ii) U.S. Design Patent Application No. 29/484,069, filed on Mar. 5, 2014 and titled “CORRUGATED ELEMENTS FOR DEFINING LONGITUDINAL CHANNELS IN A BOAT FOR A DEPOSITION APPARATUS,” (“the '069 Design Application); (iii) U.S. Design Patent Application No. 29/482,760, filed on Feb. 21, 2014 and titled “HEXCELL CHANNEL ARRANGEMENT FOR USE IN A BOAT FOR A DEPOSITION APPARATUS,” (“the '760 Design Application”); and (iv) U.S. patent application Ser. No. 13/737,737, filed on Jan. 9, 2013 and titled “PRECURSOR SUPPLIES, MATERIAL PROCESSING SYSTEMS WITH WHICH PRECURSOR SUPPLIES ARE CONFIGURED TO BE USED AND ASSOCIATED METHODS,” (“the '737 Application”), in which a claim for the benefit of priority to U.S. Provisional Patent Application No. 61/585,150, filed on Jan. 10, 2012 and titled “PRECURSOR SUPPLIES, MATERIAL PROCESSING SYSTEMS WITH WHICH PRECURSOR SUPPLIES ARE CONFIUGURED TO BE USED AND ASSOCIATED METHODS,” (“the '150 Provisional Application”) has been made pursuant to 35 U.S.C. §119(e).

A claim for the benefit of priority is also made, pursuant to 35 U.S.C. §119(e), to the Mar. 1, 2014 filing date of U.S. Provisional Patent Application No. 61/946,709, titled “MATERIAL PROCESSING SYSTEMS INCLUDING A CARRIER SYSTEM, CARRIER SYSTEMS FOR INTRODUCING PRECURSOR MATERIALS INTO MATERIAL PROCESSING SYSTEMS, CARRIERS AND CUPS OF A CARRIER SYSTEM, AND ASSOCIATED METHODS,” (“the '709 Provisional Application”).

The entire disclosures of the '643 Design Application, the '069 Design Application, the '760 Design Application, the '737 Application, the '150 Provisional Application and the '709 Provisional Application are hereby incorporated herein.

### TECHNICAL FIELD

This disclosure relates generally to boats that are configured to introduce precursor materials into material deposition apparatuses and, more specifically, to boats that are configured to introduce precursor materials, such as Parylene dimers, into vaporization chambers of material deposition apparatuses. Even more specifically, this disclosure relates to boats that have a base defined by convergent sections or extensions of at least two opposite side walls, as well as to vaporization chambers that may have at least one surface configured complementarily to such a boat. This disclosure also relates to multi-celled structures, which may be used with a boat according to this disclosure, with any other configuration of boat or without a boat, that provide a plurality of somewhat vertically oriented sub-containers that effectively increase the surface area of a precursor material and facilitate its vaporization or sublimation with improved efficiency. In addition to boats and other apparatuses for introducing precursor materials into vaporization chambers of material deposition apparatuses, this disclosure relates to vaporization chambers of material deposition apparatuses that volatilize and subsequently deposit material, to material deposition apparatuses and to methods for introducing precursor materials into the vaporization chambers of material deposition apparatuses.

### RELATED ART

Material deposition apparatuses have long been used to apply materials to substrates. As the type of process (e.g., the physical reaction, the chemical reaction, etc.) that is required to deposit a particular type of material varies from material to material, a wide variety of different types of material deposition apparatuses have been developed. In addition, many types of material deposition apparatuses have been improved based on a variety of needs, including, without limitation, the purity of the material to be deposited, the confluence of a deposited film, the thickness of the deposited film, throughput requirements, desired deposition times, and a variety of other parameters relating to the deposited material, the deposition process and the substrate(s) upon which material is to be deposited.

Parylene (poly(para-xylylene) or polyp-xylylene)) is a material that may be formed as a film that has excellent moisture-resistant properties—particularly, impermeability to moisture. Because of its moisture-resistant properties, Parylene has found widespread use in variety of contexts, including, but not limited to, on printed circuit boards (PCBs) and on or in implantable medical devices. Conventionally, Parylene has been deposited onto substrates by a form of chemical vapor deposition (CVD) process, in which a precursor material is split into monomers that are then allowed to deposit and polymerize on a substrate. More specifically, Parylene deposition typically includes vaporizing or sublimating a precursor material, pyrolyzing the precursor material to form reactive monomers and depositing the reactive monomers and allowing them to polymerize. Precursor materials that are useful in Parylene deposition processes include, without limitation, unsubstituted precursor materials (i.e., Parylene N, or [2.2] paracyclophane) and halogen-substituted precursor materials (e.g., Parylene C (which includes a single chlorine atom per aromatic ring), Parylene D (which includes two chlorine atoms per aromatic ring), Parylene AF-4 and Parylene VT-4 (both of which include fluorine atoms on each aromatic ring, etc.). The precursor materials are usually provided in powder form, and are introduced into a vaporization chamber of a CVD apparatus. The act of vaporization or sublimation typically involves heating the precursor material in the vaporization chamber. Once the precursor material has been vaporized or sublimated, it may be drawn into a pyrolyzer, where it is heated to a much higher temperature (e.g., about 550° C. to about 680° C., etc.) sufficient to “crack” the dimers into reactive monomers. The reactive monomers are then drawn into a deposition chamber, where they may be deposited onto one or more substrates and polymerize to form a film on each substrate within the deposition chamber.

When conventional CVD equipment is used for high throughput processes, large quantities of precursor material are typically introduced into the vaporization chamber. Thus, large boats are typically required when high throughput processes are conducted. To vaporize or sublimate the precursor material within a boat, heat is typically applied to the outer surfaces of the boat. Initially, precursor material located closest to the heated surfaces of the boat vaporizes or sublimates. Eventually, the heat is transferred throughout the quantity of precursor material within the boat. However, due at least in part to the conventional configurations of boats, material within the center of the boat cannot escape into the atmosphere (i.e., air or gas(es)) within the vaporization chamber. The heated material instead fuses to adjacent particles, a phenomenon that may be referred to as “sintering,” forming clumps or cakes of precursor material that effectively reduce the surface area of the precursor material and, therefore, the precursor material cannot vaporize or sublimate efficiently and, thus, that lead to a much slower rate of vaporization of the precursor material.

### SUMMARY

Boats that are configured to efficiently vaporize or sublimate a precursor material are disclosed. For the sake of simplicity, the term “vaporize,” as used hereinafter, encompasses vaporization, sublimation and other processes that enable a precursor material to be dispersed through air, another mixture of gases or a gas. A boat according to this disclosure may be configured to enable vaporization or sublimation with improved efficiency. In some embodiments, the boat may include fins that form a plurality of cells that extend vertically along the height of an interior of the boat. The cells increase the surface area of the precursor material, or at least partially maintain the surface area of the precursor material by limiting the sizes of any clumps of the precursor material that are formed as the precursor material is heated, and, since they extend vertically (or at least partially vertically), increase the number of physical paths that vaporized or sublimated precursor material may travel to escape the interior of the boat. Some embodiments of precursor materials may continue to form clumps or cakes in the cells, but in a smaller, more controlled fashion with a relative larger exposed area of precursor material, i.e., in separate cells, so that the clumps or cakes are less likely to block pathways for the vapor to escape. Thus, the fins and the cells they define may reduce or eliminate the likelihood that a precursor material will be heated in a manner that effectively reduces a surface area of the precursor material and, thus, reduces its volatilization (e.g., vaporization, sublimation, etc.) rate, or has any other detrimental effect on the usefulness of the precursor material. Vaporization chambers that are configured to receive and heat such boats and the precursor materials contained by such boats are also disclosed, as are material deposition apparatuses including the vaporization chambers and the boats.

Generally, a boat according to this disclosure includes side walls and a base that are arranged to define a container with an interior. The base and, optionally, all or part of at least some of the side walls may comprise heat-conducting surfaces (e.g., they may comprise a thermally conductive material, such as steel, stainless steel, aluminum, a ceramic, etc.) that define the interior of the container and that convey heat into the interior of the container.

Among various embodiments, a boat according to this disclosure may be configured in such a way that every location within its interior is located within a predetermined distance (e.g., one inch (about 25 mm), three-quarters of an inch (about 20 mm), one-half inch (about 15 mm), one-quarter inch (about 5 mm), etc.) of a heat-conducting surface. Thus, the boat and its interior may be configured to place all of the contents of the boat within the predetermined distance of a heated surface. Without limitation, the base of the boat may be formed by side walls that converge. In various embodiments, the base may include a single, convex surface, a plurality of convex surfaces joined at angles, a plurality of flat surfaces that are oriented relative to one another at angles or a combination of convex and flat surfaces.

The side walls of a boat according to this disclosure may have any suitable configuration. In some embodiments, the side walls of one boat may be configured to enable that boat to be assembled with one or more other boats. These boats may be configured complementarily to one another. In some embodiments, the boats may be configured similarly or even identically to one another.

In a specific embodiment, a boat may have a pair of opposite side walls, or end walls, that are oriented parallel to one another and that, when the boat rests upon its base, will be oriented vertically. These side walls, which differ from side walls that are continuous with the base of the boat, are also referred to herein as “end walls.” The base, along with side walls that are continuous with the base, may comprise an elongated strip located between the bottom edges of the two end walls. The elongated strip may comprise a single element or a plurality of sections that are secured in place relative to one another (e.g., welded end-to-end, etc.). Even more specifically, a configuration of the elongated strip may comprise a segment of a cylinder (i.e., a cylindrical segment) (e.g., a semi-cylindrical configuration, etc.) or crescent configuration that defines the base of the boat, with a configuration of each end wall of the boat comprising a segment of a circle (i.e., a circular segment) (e.g., a semi-circular configuration, etc.). Two or more boats having such a configuration may be arranged end-to-end to provide a longer assembly of boats that has a cylindrical segment configuration.

In some embodiments, one or more fins may extend through the interior of the boat. The fins may provide an increased surface area, which increases the overall surface area of the precursor material past which volatilized precursor material may escape from a quantity of precursor material that has not yet been volatilized. . Each fin may be configured to extend vertically or at least somewhat vertically throughout the interior of the boat, with a height that enables the fin to extend completely through a quantity of precursor material within the interior of the boat. The internal fin(s) may divide the interior of the container into two or more sub-containers, or cells. Some embodiments of internal fins may be configured to separate the interior of the container into small, vertically oriented sub-containers, or cells, which may be configured as hexagonal prisms, as columns with lemon-shape cross-sections taken along their heights, or lengths, or any other suitable shape.

Each fin may effectively increase the surface area of the precursor material and may provide one or more pathways for vaporized or sublimated precursor material to escape the boat as the precursor material is radiantly heated. In some embodiments, the fins and, optionally, the boat, may be formed from a consolidated (e.g., by sintering, with a suitable adhesive material, with a carrier, etc.) quantity of precursor material. Alternatively, the fins may be formed from any material that will withstand the conditions to which the boat and the precursor material will be subjected during vaporization or sublimation without reacting with the precursor material. Some embodiments of a fin may comprise a thermally conductive material (e.g., steel, stainless steel, aluminum, a ceramic, etc.) that provides for efficient thermal communication with a heat-conductive surface defining the interior of the container (e.g., the base and/or a thermally conductive side wall of the boat, another fin, etc.).

In some embodiments, fins may be used without a boat. The cells that are defined by the fins may contain a precursor material as it is placed in and resides within a vaporization chamber of a material deposition apparatus.

A vaporization chamber of a material deposition apparatus may include a receptacle for one or more boats with bases that are defined by convergent portions or extensions of two or more side walls. In some embodiments, the receptacle of the vaporization chamber may be configured to receive a plurality of boats that are arranged end-to-end. Accordingly, such a receptacle may have a configuration that complements the configuration of the base of a single boat, as well as the configurations of a plurality of boats that have been positioned adjacent to one another. Without limitation, a configuration of the receptacle of a vaporization chamber may comprise a cylindrical segment. Such a receptacle may be defined by or positioned in thermal communication with a single, elongated heating element that has been formed into the general shape of a surface of a cylindrical segment. Receptacles that lack a complementary fit with one or more boats are also within the scope of this disclosure.

The vaporization chamber may communicate with a pyrolysis tube of the material deposition apparatus. The pyrolysis tube may, in turn, communicate with a deposition chamber of the material deposition apparatus.

In use, prior to depositing a material onto one or more substrates, a determination may be made as to the quantity or amount (e.g., weight, volume, etc.) of precursor material needed to deposit a layer or film of material of a desired thickness onto a predetermined number of substrates. Once that volume has been determined, it may be introduced into one boat or split between a plurality of boats. The boats that carry the precursor material may then be introduced into the vaporization chamber (e.g., in an end-to-end fashion, etc.). Once all of the boats have been arranged in the vaporization chamber, the vaporization chamber may be closed. With the material in the vaporization chamber, heat may be applied to each boat therein (e.g., simultaneously, sequentially, etc.) to initiate a material deposition process.

Other aspects, as well as features and advantages of various aspects, of the disclosed subject matter will become apparent to those of ordinary skill in the art through consideration of the ensuing description, the accompanying drawings and the appended claims.

### BRIEF DESCRIPTION OF THE DRAWINGS

In the drawings:

FIGS. 1-3 illustrate a specific, but non-limiting embodiment of a boat that is configured to carry a quantity of a precursor material to be introduced into a vaporization chamber of a material deposition apparatus;

FIGS. 4 and 5 depict another embodiment of a boat that is configured to carry a quantity of precursor material to be introduced into a vaporization chamber of a material deposition apparatus;

FIG. 6 illustrates the embodiment of boat shown in FIGS. 1-3 with an embodiment of internal fin within the interior of its container;

FIG. 7 shows the embodiment of boat shown in FIGS. 1-3 with another embodiment of internal fin within the interior of its container;

FIG. 8 depicts the embodiment of boat illustrated by FIGS. 1-3 with yet another embodiment of internal fin within its interior;

FIG. 9 depicts an embodiment of an arrangement of a plurality of boats; more specifically, FIG. 9 shows a plurality of boats of the type shown in FIGS. 1-3 in an end-to-end arrangement;

FIG. 10 depicts an embodiment of vaporization chamber configured to receive one or more boats, such as those depicted by FIGS. 1-3; and

FIG. 11 provides a schematic representation of a material deposition apparatus that includes a vaporization chamber (see, e.g., FIG. 10) with which one or more boats (see, e.g., FIGS. 1-3) may be used.

### DETAILED DESCRIPTION

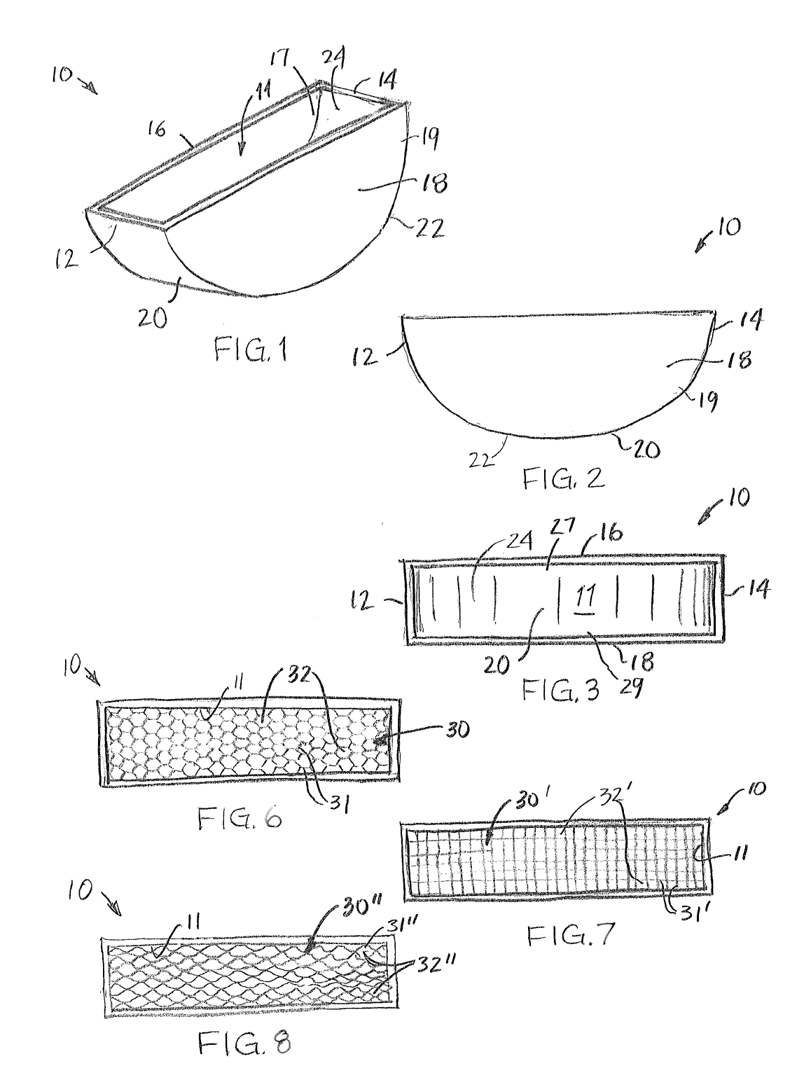

FIGS. 1-3 illustrate an embodiment of a boat 10 that comprises a container for introducing a precursor material 70 (FIG. 11) into a material deposition apparatus 200 (FIG. 11). The boat 10 comprises a container with an interior 11 defined by one or more side walls 12, 14, 16 and 18 (four are depicted in FIGS. 1-3) and a base 20.

In the specific embodiment of boat 10 depicted by FIGS. 1-3, two of the side walls 12 and 14 are located adjacent to opposite ends of the base 20. More specifically, the side walls 12 and 14 may be continuous with the base 20. Together, these side walls 12 and 14 and the base 20 may define an elongated element with a convex surface 22 and an opposite, concave surface 24. The convex surface 22 defines an exterior side or a bottom of the base 20, while the concave surface 24 defines an interior side or a top of the base 20. In the specific embodiment depicted by FIGS. 1-3, the base 20 has a cylindrical segment configuration or a crescent configuration.

The other side walls 16 and 18 of the embodiment of boat 10 depicted by FIGS. 1-3 may be positioned on opposite sides of the base 20. Thus, the side walls 16 and 18 may be spaced apart from one another. In addition, the side walls 16 and 18 may be oriented parallel to each other. The side walls 16 and 18 may comprise thin, flat elements that define opposite ends of the boat 10. Accordingly, the side walls 16 and 18 may also be referred to herein as “end walls.” In the specific embodiment depicted by FIGS. 1-3, each side wall 16, 18 comprises a segment of a circle.

Opposite side edges 27 and 29 of the base 20 and of the elongated element of which the base 20 is at least a part may be configured for assembly with (i.e., to be positioned against) and, optionally, to be secured to corresponding bottom edges 17 and 19 of side walls 16 and 18, respectively. In embodiments where the base 20 is configured as a cylindrical segment, its side edges 27 and 29 may be configured as arcs, while the bottom edges 17 and 19 of the side walls 16 and 18 may be configured as complementary arcs.

The base 20 and side walls 12, 14, 16 and 18 of the boat 10 define the interior 11 of the boat 10, which is configured to receive a quantity of a precursor material 70 (FIG. 8).

The base 20 and the side walls 12, 14, 16 and 18 may be formed from a material that will withstand prolonged and, optionally, repeated exposure to the conditions (e.g., temperature, pressure, etc.) that may be present within the vaporization chamber 210 (FIG. 11) of a material deposition apparatus 200 (FIG. 11). In addition, the materials from which the base 20 and the side walls 12, 14, 16 and 18 are formed may contact a precursor material 70 (FIG. 11) without reacting with the precursor material 70.

In some embodiments, the base 20 and, optionally, at least some of the side walls 12, 14, 16 and 18 may comprise heat-conducting surfaces. Thus, in addition to primarily radiantly heating the precursor material 70 (FIG. 11) within the interior 11 of the boat 10, in embodiments where the base 20 and, optionally, one or more of the side walls 12, 14, 16, 18 includes a heat-conducting surface or comprises a thermally conductive material, heat may be secondarily conductively conveyed into the interior 11 of the boat 10 and to any precursor material 70 within the interior 11 of the boat 10. A thermally conductive base 20 and/or side walls 12, 14, 16, 18 may be formed from or otherwise comprise a material such as aluminum, stainless steel, steel, ceramic materials, glass materials and the like.

As shown in FIGS. 1-3, a top portion of the interior 11 of the boat 10 is open to an exterior of the boat 10, which enables precursor material 70 (FIG. 11) to be readily introduced into the interior 11. The open interior 11 also facilitates the ready removal of precursor material 70 from the interior 11 of the boat 10, for example, as the precursor material 70 is vaporized, such as by heating the boat 10 or portions thereof and precursor material 70 within the interior 11 of the boat 10.

The boat 10 may have a configuration that enables precursor material 70 (FIG. 11) within the interior 11 of the boat 10 to be efficiently vaporized. In some embodiments, a configuration of the boat 10 may tailor the manner in which the precursor material 70 is vaporized, and may even optimize or maximize the efficiency with which the precursor material 70 is vaporized. In some embodiments, a shape and dimensions of the boat 10 may be configured to enable the precursor material 70 to be vaporized in a desired manner.

FIGS. 4 and 5 depict another embodiment of boat 10′ with a number of optional features that differ from corresponding features of the boat 10 shown in FIGS. 1-3. For example, the base 20′ of the embodiment boat 10′ depicted by FIGS. 4 and 5 is shallow relative to the base 20 of the embodiment of boat 10 shown in FIGS. 1-3. Optionally, the upper edges of side walls 12′ and 14′ located on opposite sides of the base 20′ need not be parallel to one another. In such an embodiment, the side walls 16′ and 18′ also have different sizes from one another.

Among various embodiments (and with returned reference to FIGS. 1-3), a boat 10 according to this disclosure may configured in such a way that every location within its interior 11 is located within a predetermined distance of a heat-conducting surface (e.g., the base 20, a sidewall 12, 14, 16, 18, etc.). Thus, the boat 10 and its interior 11 may be configured to place all of the contents of the interior 11 of the boat 10 (e.g., a precursor material 70 (FIG. 11), etc.) within the predetermined distance of a heated surface (e.g., the base 20, a sidewall 12, 14, 16, 18, etc.). Without limitation, each location within the interior 11 of a boat 10 may be within one inch (about 25 mm), three-quarters of an inch (about 20 mm), one-half inch (about 15 mm) or one-quarter inch (about 5 mm) of a heat-conducting surface of the boat 10. The embodiment of boat 10 depicted by FIGS. 1-3, in which the base 20 is formed by side walls 12 and 14 that converge, may be configured in such a way.

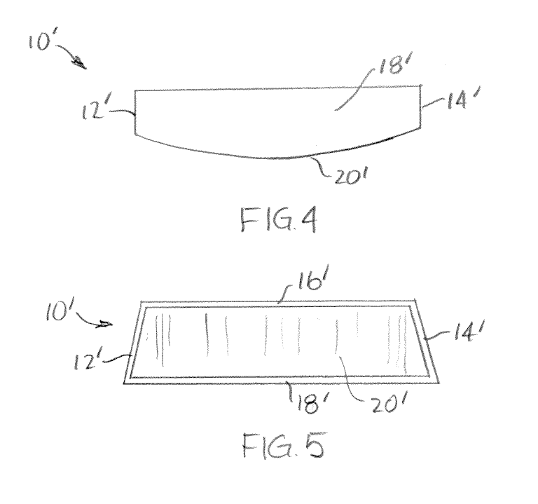

In some embodiments, such as those depicted by FIGS. 6-8, the interior 11 of the boat 10 may carry one or more fins 30, 30′, 30″, etc. The fin 30, 30′ may define a plurality of sub-containers, or cells 32, 32′, 32″, that are configured to be oriented vertically or substantially vertically (e.g., accounting for a somewhat skewed orientation of the boat 10 when it is placed within a vaporization chamber 210 (FIG. 11) of a material deposition apparatus 200 (FIG. 11), etc.) when the boat 10 rests upon its base 20. The cells 32 of the embodiment of fin 30 depicted by FIG. 6 are shape as hexagonal prisms. The embodiment of fin 30″ depicted by FIG. 7 includes cells that are shaped as parallelogram prisms or, more specifically, as square prisms. The shapes of the cross-sections of the cells 32′ of the embodiment of fin 30′ illustrated in FIG. 8, taken along the lengths of the cells 32′, are lemon-shapes. Of course, other embodiments of fins could, without departing from the scope of the disclosed subject matter, include cells that have a variety of other shapes, including any other rounded or polygonal cross-sectional shape.

The fins 30, 30′, 30″ may be formed from any suitable material. Without limitation, the material from which each fin 30, 30′, 30″ is formed may withstand the conditions to which it will be subjected within the vaporization chamber 210 (FIG. 11) of a material deposition apparatus 200 (FIG. 11). Alternatively, one or more fins 30, 30′, 30″may be formed from a consolidated quantity of the precursor material (e.g., a sintered quantity of the precursor material, precursor material that is held together by an adhesive material, precursor material that is held together by a carrier, etc.). Such fins 30, 30′, 30″) may be configured to volatilize while or after the precursor material within the cells 32, 32′, 32″ they define is volatilized. Additionally, the material from which each fin 30, 30′, 30″ is formed may be configured to contact a precursor material 70 (FIG. 11) without reacting with the precursor material 70. In some embodiments, one or more fins 30, 30′, 30″ or a portion thereof may comprise a thermally conductive material. Suitable thermally conductive materials include, but are not limited to, steel, stainless steel, aluminum, a ceramic material or the like. Other materials that may be used to form the fins include, but are not limited to, open-celled porous materials (e.g., coarse materials having a sponge-like configuration, etc.), wire cloth, consolidated precursor material (in which case the fins may also volatilize) and the like.

In some embodiments, an arrangement of fins, such as the embodiments of fins 30 and 30′ depicted by FIGS. 6 and 7, respectively, may comprise one or more assembled units, with all of their members 31 and 31′, respectively, secured to one another. In other embodiments, the members 31″ of an arrangement of fins 30″ may be separate from one another, and merely define cells 32″, or sub-containers, within the interior 11 of a boat 10 when the arrangement of fins is collectively placed in the interior 11. In the embodiment illustrated by FIG. 8, each member 31″ of the arrangement of fins 30″ comprises a corrugated sheet that has been shaped to fit within the interior 11 of the boat 10.

Regardless of their configuration, the fins 30, 30′, 30″ may be permanently secured within the interior 11 of a boat 10, or they may be configured for removal, even ready removal, from the interior 11 of the boat 10. Removability of the fins 30, 30′, 30″ from the interior 11 of the boat 10 may simplify cleaning and reuse of the boat 10. The fins 30, 30′, 30″may themselves be configured for cleaning and reuse, they may be disposable or they may comprise a precursor material and, thus, be configured for volatilization by a material deposition apparatus.

Regardless of their configuration, the fins 30, 30′, 30″ may be oriented and arranged in a manner that effectively increases the total area of the surfaces that the precursor material 70 (FIG. 11) contacts and, thus, the total surface area of the precursor material. As depicted by FIGS. 6-8, the fins 30, 30′, 30″ may extend through the entire height of the interior 11 (FIGS. 1-3) of a boat 10 or through substantially the entire height of the interior 11 (e.g., a gap may exist between the bottom edge of each fin 30, 30′, 30″ and the base 20 of the boat 10, etc.) and, thus, through the entire height or substantially the entire height of a precursor material 70. In some embodiments, an upper portion of each fin 30, 30′, 30″ may protrude from a quantity of the precursor material (e.g., by 0.5 cm or more, by 1 cm or more, by 2 cm or more, etc.). Fins 30, 30′, 30″ with upper portions that protrude beyond an upper surface of precursor material may capture radiant heat and direct it into the cells 32, 32′, 32″, which may controlled heating of the precursor material from the top, down. In addition, each surface of a fin 30, 30′, 30″ that contacts precursor material 70 may provide a path for the precursor material 70 to travel (e.g., upward, out of a cell 32, 32′, 32″, etc.) once the precursor material 70 is vaporized. These features may provide chimney effect that may provide faster and more efficient vaporization or sublimation of the precursor material 70.

A boat 10 according to this disclosure may be configured for assembly or arrangement with one or more other boats 10. An embodiment of such an assembly 100 is depicted by FIG. 9. Assemblies of boats 10 enables tailoring of the amount of precursor material that is introduced into a material deposition apparatus and/or the order in which different types of precursor materials are introduced into the material deposition apparatus when a plurality of different materials are to be deposited (simultaneously, in sequence, to form a film with one or more gradients, etc.) during a process cycle.

In the assembly 100 of FIG. 9, a plurality of boats 10 having the same configuration are arranged end-to-end. Since the boats 10 in the illustrated embodiment have crescent configurations, the assembly 100 has an elongated crescent configuration.

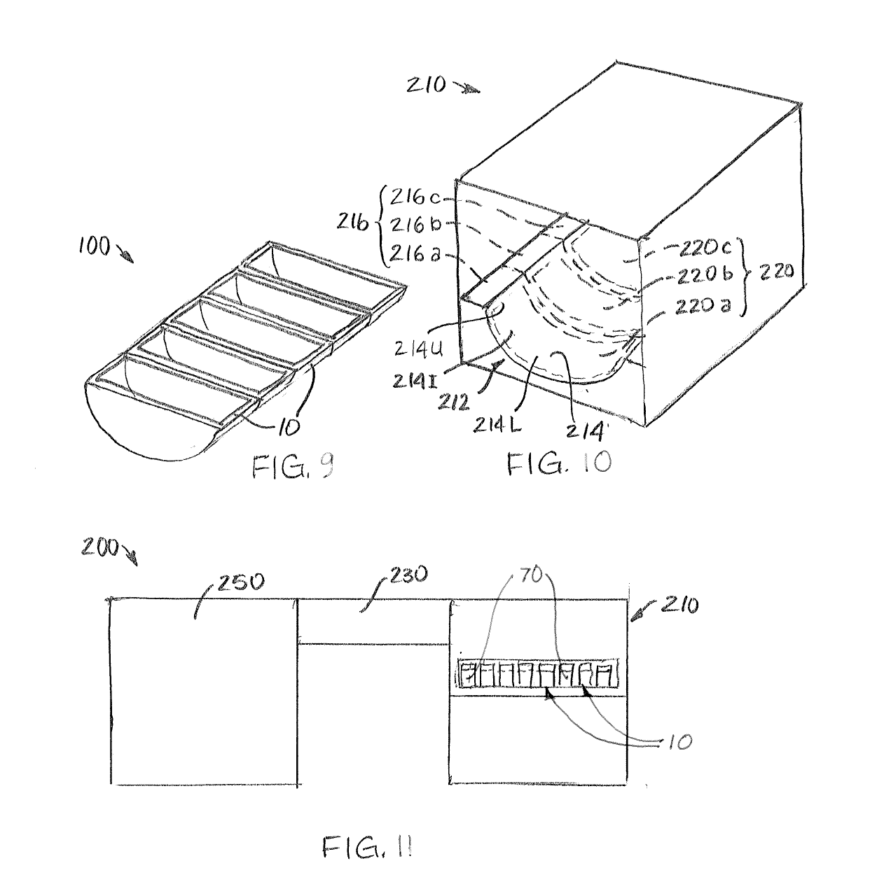

A representation of an embodiment of vaporization chamber 210 of a material deposition apparatus 200 (FIG. 11) that is configured to receive one or more boats 10 (FIGS. 1-3) according to this disclosure is provided by FIG. 10. The vaporization chamber 210 may include a boat receptacle 212 for receiving the bases 20 (FIGS. 1-3) of one or more boats 10. Since the base 20 of each boat 10 has a convex configuration (e.g., a portion of the curved surface of a cylinder, etc.), a boat-receiving surface 214 of the boat receptacle 212 may have a complementary concave configuration. This complementarity may enable optimization of the efficiency with which precursor material 70 (FIG. 11) is packed into the vaporization chamber 210. As illustrated, the boat receptacle 212 is configured to receive a plurality of boats 10 in end-to-end relation. In some embodiments, the boat receptacle 212 may include a plurality of zones 216a, 216b, 216c, etc. Each zone 216 may correspond to a boat 10.

In addition to the boat receptacle 212, the vaporization chamber 210 may include one or more heating elements 220. Each heating element 220 may be configured to heat the boat receptacle 212 or a portion thereof. In embodiments where the boat-receiving surface 214 of the boat receptacle 212 is smooth (e.g., has a curved surface, etc.), a single heating element 220 may be heat upper portions 214U, intermediate portions 214I and lower portions 214L of the boat-receiving surface 214. As shown, the vaporization chamber 210 includes a plurality of heating elements 220a, 220b, 220c, etc., which are arranged in series. Each heating element 220a, 220b, 220c, etc., may correspond to a zone 216a, 216b, 216c, etc., of the boat receptacle 212. Accordingly, the temperature of each zone 216a, 216b, 216c, etc., of the boat receptacle 212 may be controlled independently (e.g., in embodiments where the boat-receiving surfaces 214 of the zones 216a, 216b, 216c, etc., are thermally isolated form one another; etc.) from the temperature of each adjacent zone 216a, 216b, 216c, etc., or substantially independently (e.g., in embodiments wherein the boat-receiving surface 214 extends across two or more zones 216a, 216b, 216c, etc.; etc.) from the temperature of each adjacent zone 216a, 216b, 216c, etc.

Independent or substantially independent control over the temperatures of the different zones 216a, 216b, 216c, etc., of the boat receptacle 212 may provide for vaporization or sublimation of material in different boats 10 in a controlled manner. Without limitation, material within different boats 10 may be vaporized or sublimated simultaneously, from one boat 10 at a time (i.e., sequentially), or sequentially with some overlap, which may provide for gradients in the deposited material.

FIG. 11 illustrates an embodiment of a material deposition apparatus 200 of which the vaporization chamber 210 is a part and, of course, with which one or more boats 10 may be used. In addition the vaporization chamber 210, the material deposition apparatus 200 includes a pyrolysis tube 230 and a deposition chamber 250, among a variety of other features. Such a material deposition apparatus 200 may be configured to deposit a substituted or unsubstituted poly(p-xylylene) polymer, or parylene, onto one or more substrates. U.S. Patent Application Publication No. 2013/0251889 A1, the entire disclosure of which is hereby incorporated herein, discloses an embodiment of such a material deposition apparatus 200. Others are also within the scope of this disclosure.

Although the foregoing disclosure provides many specifics, these should not be construed as limiting the scope of any of the appended claims, but merely as providing information pertinent to some specific embodiments that may fall within the scopes of the claims. Other embodiments may be devised which lie within the scopes of the claims. Features from different embodiments may be employed in any combination. All additions, deletions and modifications, as disclosed herein, that fall within the scopes of the claims are to be embraced by the claims.

What is claimed:

1. A material deposition apparatus, comprising:
a vaporization chamber including a concave surface for receiving at least one boat; and
at least one boat for introducing a precursor material into the vaporization chamber, the at least one boat including a convex surface configured complementarily to the concave surface of the vaporization chamber.

2. The material deposition apparatus of claim 1, wherein the concave surface of the vaporization chamber comprises a portion of a curved surface of a cylinder.

3. The material deposition apparatus of claim 2, wherein the convex surface of the at least one boat comprises a portion of a curved surface of a cylinder.

4. The material deposition apparatus of claim 1, wherein the at least one boat has a configuration of a sector of a cylinder.

5. The material deposition apparatus of claim 1, wherein the at least one boat includes end walls on opposite ends of the concave surface, the end walls being oriented substantially parallel to one another.

6. The material deposition apparatus of claim 5, comprising a plurality of boats configured to be arranged adjacent to one another, with convex surfaces of the plurality of boats configured to be arranged along a length of the concave surface of the boat receptacle of the vaporization chamber and end walls of adjacent boats being positioned adjacent to one another.

7. The material deposition apparatus of claim 1, comprising a plurality of boats configured to be arranged adjacent to one another, with convex surfaces of the plurality of boats configured to be arranged over the concave surface of the boat receptacle of the vaporization chamber.

8. The material deposition apparatus of claim 1, wherein the concave surface of the boat receptacle is configured to deliver heat to the base of at least one boat.

9. The material deposition apparatus of claim 8, wherein the vaporization chamber further includes a heating element associated with the concave surface of the boat receptacle.

10. The material deposition apparatus of claim 9, comprising a single heating element associated with the concave surface of the boat receptacle.

11. The material deposition apparatus of claim 9, wherein the concave surface of the boat receptacle is defined by the heating element.

12. A boat for use with a material deposition apparatus, comprising:
a plurality of side walls; and
a base,
the plurality of side walls and the base defining an interior of the boat, at least one of a side wall and the base imparting a bottom of the boat with a convex configuration.

13. The boat of claim 12, wherein the plurality of side walls includes a pair of opposite end walls.

14. The boat of claim 13, wherein the base and a pair of opposite side walls extend between the end walls.

15. The boat of claim 14, wherein the base and the pair of opposite side walls impart the bottom of the boat with the convex configuration.

16. The boat of claim 15, wherein the sidewalls of the pair of opposite side walls are continuous with ends of the base.

17. The boat of claim 16, wherein the pair of opposite side walls and the base are configured as a portion of a curved surface of a cylinder.

18. The boat of claim 12, further comprising:
a plurality of somewhat vertically oriented cells within the interior of the boat.

19. The boat of claim 12, wherein each location within the interior of the boat is located within 25 mm of the base or at least one of the plurality of side walls.

20. The boat of claim 12, wherein each location within the interior of the boat is located within 15 mm of the base or at least one of the plurality of side walls.

21. A carrier for introducing a precursor material into a vaporization chamber of a material deposition apparatus, the carrier comprising:
a plurality of cells positioned adjacent to one another, each cell of the plurality of cells being oriented somewhat vertically relative to the base, each cell of the plurality of cells configured to receive a quantity of the precursor material.

22. The carrier of claim 21, further comprising:
a precursor material within at least some cells of the plurality of cells.

23. The carrier of claim 22, wherein the precursor materials comprises a precursor to a parylene.

24. The carrier of claim 22, wherein walls defining the cells extend vertically above the precursor material.

25. The carrier of claim 21, wherein each cell of the plurality of cells is configured to promote a chimney effect as precursor material therein is volatilized.

26. The carrier of claim 21, further comprising:
a boat including an interior for receiving the plurality of cells.

27. A method for introducing a precursor material into a material deposition apparatus, comprising:
placing a boat containing a quantity of precursor material into a vaporization chamber of a material deposition apparatus, a convex surface of the boat being received by a complementarily configured concave surface of a boat receptacle.

28. The method of claim 27, further comprising:
placing another boat containing a quantity of precursor material into the vaporization chamber of the material deposition apparatus, a convex surface of the another boat being received by the complementarily configured concave surface of the boat receptacle, a side wall of the another boat being positioned against a side wall of the boat.

29. The method of claim 28, further comprising:
heating the concave surface of the boat receptacle to heat the boat and the quantity of precursor material within the boat and to vaporize or sublimate the quantity of precursor material.

30. The method of claim 29, wherein heating the concave surface comprises heating the concave surface in a manner that heats at least one boat within the vaporization chamber to a temperature sufficient to cause the quantity of precursor material therein to vaporize or sublimate, but does not heat at least one boat within the vaporization chamber to a temperature sufficient to cause precursor material within that at least one boat to vaporize or sublimate.
